(19) United States
(12) Patent Application Publication
(10) Pub. No.: US 2021/0074899 A1
(43) Pub. Date: Mar. 11, 2021

(54) HIGH-ENTROPY HALF-HEUSLER THERMOELECTRIC MATERIAL WITH LOW LATTICE THERMAL CONDUCTIVITY AND PREPARATION METHOD THEREOF

(71) Applicant: Dalian University of Technology, Dalian City (CN)

(72) Inventors: Huijun KANG, Dalian City (CN); Tongmin WANG, Dalian City (CN); Xiong YANG, Dalian City (CN); Zongning CHEN, Dalian City (CN); Enyu GUO, Dalian City (CN); Tingju LI, Dalian City (CN); Zhiqiang CAO, Dalian City (CN); Yiping LU, Dalian City (CN); Jinchuan JIE, Dalian City (CN); Yubo ZHANG, Dalian City (CN)

(21) Appl. No.: 16/738,348

(22) Filed: Jan. 9, 2020

(30) Foreign Application Priority Data
Sep. 10, 2019 (CN) 201910850656.5

(51) Int. Cl. H01L 35/20; C22C 1/04; C22C 30/04

(52) U.S. Cl. CPC H01L 35/20; C22C 30/04; C22C 1/04

(57) ABSTRACT

The present invention provides a high-entropy Half-Heusler thermoelectric material with a low lattice thermal conductivity and a preparation method thereof. The general formula of the high-entropy Half-Heusler thermoelectric material with a low lattice thermal conductivity is ZrₓHf₁₋ₓNi_{y}Pd_{1-y}Sn, where x is equal to 0.6 to 0.8, and y is equal to 0.8 to 0.9. The preparation method of the high-entropy Half-Heusler thermoelectric material with a low lattice thermal conductivity comprises the following steps: preparing and mixing materials according to the general formula of Zr_{0.7}Hf_{0.3}Ni_{0.85}Pd_{0.15}Sn, putting the mixed raw materials in a levitation melting for melting, grinding the obtained ingot into powder and drying it, and sintering the powder by using spark plasma sintering into a bulk high-entropy Half-Heusler thermoelectric material with a low lattice thermal conductivity. The high-entropy Half-Heusler thermoelectric material of the present invention has a relatively low lattice thermal conductivity and a relatively high ZT value.

### CROSS-REFERENCE TO RELATED APPLICATION

This application claims priority to Chinese Patent Application No. 201910850656.5, filed Sep. 10, 2019, the entire contents of which are hereby incorporated by reference in their entirety.

### TECHNICAL FIELD

The present invention relates to a thermoelectric material, in particular to a high-entropy Half-Heusler thermoelectric material with a low lattice thermal conductivity and a preparation method thereof.

### BACKGROUND

Thermoelectric material is a functional material capable of directly mutually converting thermal energy and electric energy. Thermoelectric generation is an important field of energy conversion technology, which can realize the power generation by waste heat and thus relieve the world-wide problem of energy shortage; thermoelectric refrigeration is an environmentally-friendly technology, and can be widely applied to small-scale fluoride-free and local refrigeration. As everyone knows, Half-Heusler alloy with semiconductor characteristic or Seebeck effect is a typical medium and high temperature thermoelectric material, showing a potential application prospect in the field of thermoelectric power generation.

The performance of a thermoelectric material mainly depends on its thermoelectric figure of merit ZT. The larger the ZT value, the higher the thermoelectric conversion efficiency is. The thermoelectric figure of merit can be defined as ZT=α²σT/κ, where α is Seebeck coefficient, sigma is conductivity, α²σ also can be called the power factor PF, T is absolute temperature, κₗ is total thermal conductivity, including lattice (phonon) thermal conductivity κₗ and electronic thermal conductivity κₑ, that is κ=9κₗ+κₑ. However, due to the interdependent thermoelectric parameters (α, σ and κₑ) on carrier concentration n, it is indeed a challenge about how to effectively improve the ZT value in academic world. A high conductivity sigma usually leads to a low Seebeck coefficient α and a high electronic thermal conductivity κₑ. The total thermal conductivity mainly consists of lattice thermal conductivity and electronic thermal conductivity. As for the doped Half-Heusler alloy, the lattice thermal conductivity plays a dominant role in the total thermal conductivity owing to the low contribution of the electronic conductivity. Therefore, the ZT value of doped Half-Heusler alloys can be effectively improved by substantially reducing the lattice thermal conductivity.

### SUMMARY

To resolve the problem that it is so hard to effectively enhance the ZT value for a thermoelectric material, the present invention provides a high-entropy Half-Heusler thermoelectric material with a relatively low lattice thermal conductivity and a high ZT value.

To achieve the above purpose, the present invention adopts the following technical solution: A high-entropy Half-Heusler thermoelectric material with a low lattice thermal conductivity is prepared, where its general formula is ZrₓHf₁₋ₓNi_{y}Pd_{1-y}Sn, in which x is equal to 0.6 to 0.8, and y is equal to 0.8 to 0.9; and preferably, the general formula is Zr_{0.7}Hf_{0.3}Ni_{0.85}Pd_{0.15}Sn.

Another objective of the present invention is to provide a preparation method of a high-entropy Half-Heusler thermoelectric material with a low lattice thermal conductivity, including the following steps: preparing and mixing materials in a glovebox according to the general formula of ZrₓHf₁₋ₓNi_{y}Pd_{1-y}Sn, in which x is equal to 0.6 to 0.8 and y is equal to 0.8 to 0.9, then putting a mixture in a levitation melting furnace for melting, and grinding obtained ingots into powder and drying the powder, and finally sintering the powder by spark plasma sintering to obtain the high-entropy Half-Heusler thermoelectric material with a low lattice thermal conductivity.

Further, the preparation method of a high-entropy Half-Heusler thermoelectric material with a low lattice thermal conductivity includes the following steps:

(1) preparing and mixing materials according to the general formula of ZrₓHf₁₋ₓNi_{y}Pd_{1-y}Sn in a glovebox;

(2) putting a mixture in a levitation melting furnace for melting under an argon atmosphere, raising the temperature to 1600-1800° C., and holding the temperature for 1-5 min, and the optimal heating process is: raising the temperature to 1650-1750° C., and holding the temperature for 3-5 min;

(3) ball-milling obtained ingots into powder with the diameter of 0.5-2 optimally 0.5-1 μM.

(4) drying the obtain powder; and

(5) sintering the powder by spark plasma sintering, where the sintering temperature is 800-1000° C., the sintering pressure is 80-100 MPa, and the holding time is 5-20 min; optimally, the sintering temperature is 900-1000° C., the sintering pressure is 90-100 MPa, and the holding time is 10-20 min.

Further, the pressure of the argon atmosphere in the step (2) is 10⁴-10⁵ Pa.

Further, the melting in the step (2) is performed 3-6 times.

Further, the ball-milling in the step (3) includes the following steps: firstly, roughly grinding the ingot into powder with the diameter of 0.1-1 mm by using a mortar and pestle, and then carrying out wet ball-grinding under an argon atmosphere, where the ball-milling medium is absolute ethyl alcohol, and the mass ratio between balls and powder is 10:1 to 20:1, the rotating speed is 200-600 r/min, and the ball-milling time is 5-20 h.

Further, the step of drying in step (4) includes the step of naturally drying the powder for 12-48 h after suction filtration in a glovebox, optimally for 12-24 h.

The high-entropy Half-Heusler thermoelectric material with a low lattice thermal conductivity and a preparation method has the following advantages compared with the current technology:

A ZrNiSn alloy is selected as a master template of a high-entropy Half-Heusler thermoelectric alloy. Hf and Pd isoelectronic structural heavy substitutions (greater than 5 at. %) are selected as Zr and Ni sites respectively. A large element solid solubility is obtained through a high-entropy effect, and finally a five-component high-entropy thermoelectric material is formed. The high-entropy Half-Heusler thermoelectric material was prepared by levitation melting and spark plasma sintering, the phase compositions of all samples are characterized by XRD, and the thermal diffusivity is measured by the laser flash diffusivity method above the room temperature.

XRD results confirm that the single-phase high-entropy Half-Heusler thermoelectric material is successfully prepared by using the method in present invention. The thermal diffusion coefficient of the alloy is measured by the laser flash diffusivity method, and a low total thermal conductivity of 4.09 mV/mK² is achieved at 923K, which is reduced by 17% compared with that of the pristine ZrNiSn, where the lattice thermal conductivity is as low as 2.76 mW/mK² (being reduced by 22.2% compared with that of the pristine ZrNiSn). In present invention, the high-entropy Half-Heusler thermoelectric material with a low lattice thermal conductivity is successfully obtained.

### BRIEF DESCRIPTION OF THE DRAWINGS

FIG. 1 shows XRD patterns of bulk samples with different compositions after spark plasma sintering.

FIG. 2 shows the total thermal conductivity of the pristine ZrNiSn and the Zr_{0.7}Hf_{0.3}Ni_{0.85}Pd_{0.15}Sn high-entropy Half-Heusler thermoelectric alloy.

FIG. 3 shows the lattice thermal conductivity of the pristine ZrNiSn and the Zr_{0.7}Hf_{0.3}Ni_{0.85}Pd_{0.15}Sn high-entropy Half-Heusler thermoelectric alloy.

### DETAILED DESCRIPTION OF THE DRAWINGS

The description of the present invention is further described in conjunction with the following embodiments.

### Embodiment 1

The embodiment discloses a high-entropy Half-Heusler thermoelectric material with a low lattice thermal conductivity, and it is melted according to the nominal composition of Zr_{0.7}Hf_{0.3}Ni_{0.85}Pd_{0.15}Sn, where the atomic percent of each element is as follows: Zr, 23.3%; Hf, 10%; Ni, 28.3%; Pd, 5%; and Sn, 33.3%.

The further improvement of the present invention lies in that:

The grain size of the obtained Half-Heusler thermoelectric material is 0.5-2 μm.

The preparation method of the high-entropy Half-Heusler thermoelectric material with a low lattice thermal conductivity includes the following steps:

(1) preparing materials according to the nominal composition of Zr_{0.7}Hf_{0.3}Ni_{0.85}Pd_{0.15}Sn in a glovebox;

(2) melting: mixed raw materials are melted in a levitation melting furnace under an argon atmosphere (10⁴-10⁵ Pa), after raising the temperature to 1600-1800° C., then holding the temperature for 3 min. The obtained ingot is repeatedly melted four times in order to keep the homogeneous microstructure;

(3) ball-milling: the ingot is firstly roughly grinded into powder with the diameter of 0.1-1 mm by using a mortar and pestle; and then wet ball-milling is carried out under an argon atmosphere, where the ball-milling medium is absolute ethyl alcohol, and the mass ratio between balls and powder is 15:1, the rotating speed is 500 r/min, and the ball-milling time is 10 h;

(4) drying: the powder is naturally dried for 24 h after suction filtration in a glovebox; and

(5) sintering: the prepared powder is sintered into a bulk sample by spark plasma sintering, where the sintering temperature is 900° C., the sintering pressure is 100 MPa, and the holding time is 15 min.

Experimental Result

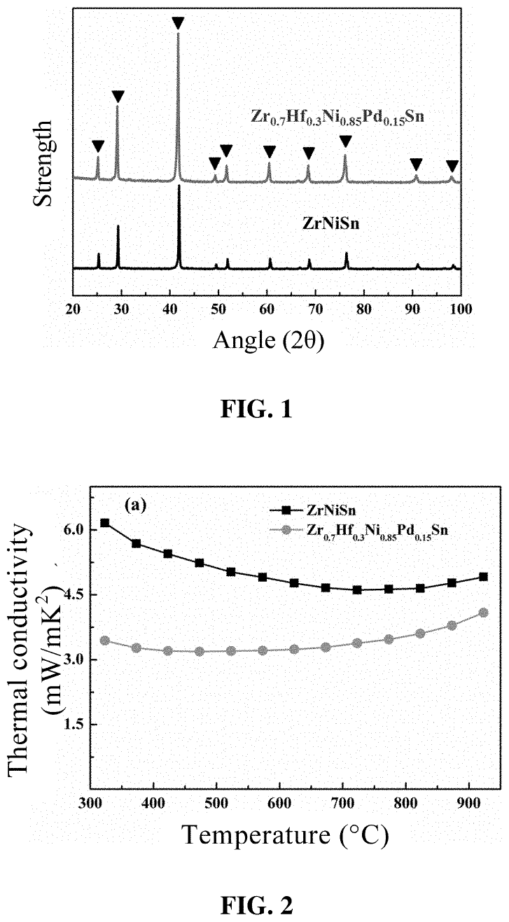

FIG. 1 shows the XRD patterns of bulk samples with different compositions after spark plasma sintering. All the XRD patterns of the pristine ZrNiSn and Zr_{0.7}Hf_{0.3}Ni_{0.85}Pd_{0.15}Sn high-entropy Half-Heusler thermoelectric samples with x≤0.06 are indexed as a single phase;

FIG. 2 shows the total thermal conductivity of the pristine ZrNiSn and Zr_{0.7}Hf_{0.3}Ni_{0.85}Pd_{0.15}Sn high-entropy Half-Heusler thermoelectric alloy. A low total thermal conductivity of 4.09 mW/mK² is achieved at 923K, which is reduced by 17% compared with that of the pristine ZrNiSn.

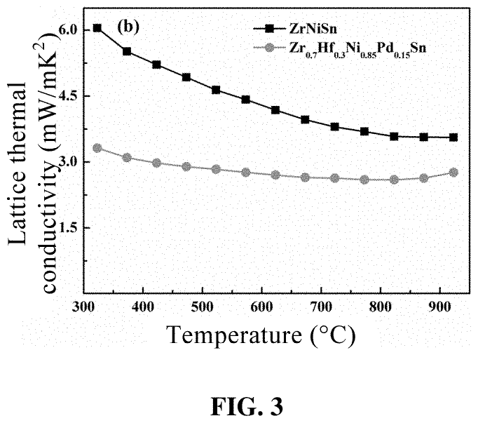

FIG. 3 shows the lattice thermal conductivity of the pristine ZrNiSn and Zr_{0.7}Hf_{0.3}Ni_{0.85}Pd_{0.15}Sn high-entropy Half-Heusler thermoelectric alloy. The lattice thermal conductivity of the high-entropy Half-Heusler alloy is reduced to 2.76 mW/mK² at 923 K, which is compared with that of the pristine ZrNiSn.

In the embodiment, a high-entropy alloy design idea is introduced into the preparation of the Half-Heusler thermoelectric alloy, so that the lattice thermal conductivity of the Half-Heusler thermoelectric alloy is remarkably reduced by an obvious lattice distortion field generated by a high-entropy effect, and it will provide more opportunities for the industrial applications of moderate and high-temperature Half-Heusler thermoelectric materials. Through the present invention, a single-phase Zr_{0.7}Hf_{0.3}Ni_{0.85}Pd_{0.15}Sn high-entropy Half-Heusler thermoelectric alloy is successfully prepared, and a low total thermal conductivity of 4.09 mW/mK² and a low lattice thermal conductivity of 2.76 mW/mK² are achieved at 923K.

### Embodiment 2

The further improvement of the present invention lies in that: The preparation method of a high-entropy Heusler alloy with a low lattice thermal conductivity includes the following steps:

(1) preparing materials according to the nominal composition of Zr_{0.6}Hf_{0.4}Ni_{0.8}Pd_{0.2}Sn in a glovebox;

(2) melting: mixed raw materials are melted in a levitation melting furnace under an argon atmosphere (10⁴-10⁵ Pa), after raising the temperature to 1600-1800° C., then holding the temperature for 4 min, The obtained ingot is repeatedly melted four times in order to keep the homogeneous microstructure; (3) ball-milling: the ingot is firstly roughly grinded into powder with the diameter of 0.1-1 mm by using a mortar and pestle; and then wet ball-milling is carried out under an argon atmosphere, where the ball-milling medium is absolute ethyl alcohol, and the mass ratio between balls and powder is 20:1, the rotating speed is 600 r/min, and the ball-milling time is 8 h;

(4) drying: the powder is naturally dried for 20 h after suction filtration in a glovebox; and

(5) sintering: the prepared powder is sintered into a bulk sample by spark plasma sintering, where the sintering temperature is 850° C., the sintering pressure is 90 MPa, and the holding time is 20 min.

Finally, it should be noted that the foregoing embodiments are merely intended for describing the technical solutions of the present invention, but not for limiting the present invention. Although the present invention is described in detail with reference to the foregoing embodiments, persons of ordinary skill in the art should understand that they may still make modifications to the technical solutions described in the foregoing embodiments or make equivalent replacements to some or all technical features thereof, without departing from the scope of the technical solutions of the embodiments of the present invention.

What is claimed is:

1. A high-entropy Half-Heusler thermoelectric material with a low lattice thermal conductivity, wherein the general formula is ZrₓHf₁₋ₓNi_{y}Pd_{1-y}Sn, wherein x is equal to 0.6 to 0.8, and y is equal to 0.8 to 0.9.

2. A preparation method of a high-entropy Half-Heusler thermoelectric material with a low lattice thermal conductivity, comprising the following steps: preparing and mixing materials according to the general formula of ZrₓHf₁₋ₓNi_{y}Pd_{1-y}Sn, in which x is equal to 0.6 to 0.8 and y is equal to 0.8 to 0.9, putting a mixture in a levitation melting furnace for melting, grinding the obtained ingot into powder and drying the powder, and sintering the powder by spark plasma sintering into a bulk high-entropy Half-Heusler thermoelectric alloy sample with a low lattice thermal conductivity.

3. The preparation method of a high-entropy Half-Heusler thermoelectric material with a low lattice thermal conductivity according to claim 2, comprising the following steps:
(1) preparing and mixing materials according to the general formula of ZrₓHf₁₋ₓNi_{y}Pd_{1-y}Sn in a glovebox;
(2) putting the mixed raw materials in a levitation melting furnace for melting under an argon atmosphere: raising the temperature to 1600-1800° C., and then holding the temperature for 1-5 min;
(3) ball-milling the obtained ingot into powder with the diameter of 0.5-2 μm;
(4) drying the obtained powder; and (5) sintering the powder by spark plasma sintering,
wherein the sintering temperature is 800-1000° C., the sintering pressure is 80-100 MPa, and the holding time is 5-20 min.

4. The preparation method of a high-entropy Half-Heusler thermoelectric material with a low lattice thermal conductivity according to claim 3, wherein the pressure of the argon atmosphere in the step (2) is 10⁴-10⁵ Pa.

5. The preparation method of a high-entropy Half-Heusler thermoelectric material with a low lattice thermal conductivity according to claim 3, wherein the melting in the step (2) is repeatedly performed 3-6 times.

6. The preparation method of a high-entropy Half-Heusler thermoelectric material with a low lattice thermal conductivity according to claim 3, wherein the ball-milling in the step (3) comprises the following steps: firstly roughly grinding the ingot into powder with the diameter of 0.1-1 mm by using a mortar and pestle, and then wet ball-grinding under an argon atmosphere, wherein the ball-milling medium is absolute ethyl alcohol, and the mass ratio between balls and powder is 10:1 to 20:1, the rotating speed is 200-600 r/min, and the ball-milling time is 5-20 h.

7. The preparation method of a high-entropy Half-Heusler thermoelectric material with a low lattice thermal conductivity according to claim 3, wherein the drying in step (4) comprises the step of naturally drying the powder for 12-48 h after suction filtration in the glovebox.
